(19) United States
(12) Patent Application Publication
(10) Pub. No.: US 2012/0305052 A1
(43) Pub. Date: Dec. 6, 2012

(54) ROTATABLE SOLAR PANEL ASSEMBLIES

(76) Inventor: Steven Grant Bruneau, Tillamook, OR (US)

(21) Appl. No.: 13/585,162

(22) Filed: Aug. 14, 2012

Related U.S. Application Data
(63) Continuation-in-part of application No. 13/013,675, filed on Jan. 25, 2011.
(60) Provisional application No. 61/336,767, filed on Jan. 26, 2010.

(51) Int. Cl. H01L 31/048

(52) U.S. Cl. 136/246

(57) ABSTRACT

Rotatable solar panel assemblies herein are configured to couple to a boat trailer, or other vehicles and structures in order to charge a battery in a boat secured on top of the trailer or to otherwise provide power to vehicles or structures. The solar panel assemblies can be configured to have means for 360 rotation to allow efficient sunlight capture and to allow for a more aerodynamic profile when the trailer is being towed. The assemblies herein include a solar panel housing that can include downwardly slanting sides to protect the one or more solar panels mounted within the housing from road debris, or other hazards.

### CROSS-REFERENCE TO RELATED APPLICATIONS

This application claims priority to and is a continuation-in-part to co-pending U.S. application Ser. No. 13/013,675, entitled “Solar Panel Assemblies for Attachment to a Boat Trailer”, filed Jan. 25, 2011 which claims priority to U.S. Provisional Application 61/336,767, filed on Jan. 26, 2010 which is expressly incorporated herein in its entirety.

### FIELD OF THE INVENTION

The embodiments herein relate to rotatable solar panel assemblies which can be configured to be attached to a boat trailer, boats, other vehicles, machines, and structures such as houses and buildings. More specifically, the teachings herein can be used to charge a battery operated watercraft coupled to and positioned on top of the boat trailer.

### BACKGROUND

Watercrafts have utilized solar energy to either fully power or supplement the boat's battery. See for example, U.S. Pat. Nos. 7,047,902, to Little, 6,805,064 to Andersen, and 6,000,353 to De Leu. As the above-listed patents show, these watercraft include designs that incorporate a solar panel positioned directly on the watercraft. This particular design strategy is disadvantageous for several reasons. Firstly, the solar panels on these vehicles are stationary as opposed to rotatable or otherwise adjustable. Their immobility prohibits efficient capture of sunlight. Furthermore, the solar panels are only configured to allow charging of the vehicles they are positioned on, as opposed to additional vehicles. Similarly, prior art solar panel exposure is limited to the particular parking limitations where the trailer is positioned, such that if it is parked under shade or cover, the solar panel cannot be adjusted to capture sunlight efficiently. Additional problems with current solar panel housing designs is that they don't alleviate the stresses incurred from traveling or inclement environments, such as high winds or water turbulence. Still further problems with the prior art is that heat is not dissipated from working solar panels efficiently.

Accordingly, there is a need in the art to provide solar panel assemblies for charging electrical batteries in watercraft, are configured to efficiently capture sunlight, allow for the charging of more than one watercraft, allow for charging even when a protective cover is placed over the watercraft, and can be oriented to more efficiently capture the sun if parked under shade, such as in a parking lot storage site. Additionally there is a need to provide rotatable solar panel assemblies to provide power to vehicles, machines, and structures that can dissipate the heat generated from the working solar panels and to alleviate stress induced from movement, or inclement environments.

### SUMMARY OF THE INVENTION

Preferred embodiments are directed to solar panel assemblies for attachment to a boat trailer and comprising: a base plate configured to traverse along the length of a structural bar positioned near the front of the boat trailer and having means for coupling to said structural bar; a support stanchion having its lower end operably coupled to the upper surface of the base plate and a upper surface configured to support the base of a solar panel housing; wherein the solar panel housing, supports a first solar panel; and means for transmitting the power of the solar panel to a battery.

Additional embodiments are directed to boat trailers comprising: a back portion configured for receiving and releasing a boat; a middle portion configured to hold the boat while secured to said trailer; a front portion configured to couple to a towing vehicle, wherein the front portion is defined as the portion of the trailer in front of the foremost point of the boat when secured in the middle position of the trailer; a base plate configured to traverse along the length of a structural bar positioned in the front portion of the boat trailer and having means for coupling to said structural bar; a support stanchion having its lower end operably coupled to the upper surface of the base plate and a upper surface configured to support the base of a solar panel housing, wherein the solar panel housing supports a first solar panel; and means for transmitting the power of the solar panel to a battery.

Further embodiments are directed to a solar panel housing assembly comprising a solar panel housing having a back panel with one or more heat dissipating slots, configured such that one or more solar panels can be supported by the back panel, and a solar panel housing base, wherein the back panel is angled with respect to the solar panel housing base; and a mount comprising means for securely coupling to the top of a support structure and having a topside having means for coupling to the base of the solar panel housing, wherein the mount and the solar panel housing base further comprise means for allowing the solar panel housing to rotate around the mount.

Further embodiments are directed to a solar panel housing assembly comprising: a solar panel housing having a back panel configured such that one or more solar panels can be supported by the back panel, the back panel further comprising compressible dampeners positioned on the topside of the back panel of the solar panel housing, and a solar panel housing base, wherein the back panel is angled with respect to the solar panel housing base; and a mount comprising means for securely coupling to the top of a support structure and having a topside having means for coupling to the base of the solar panel housing, wherein the mount and the solar panel housing base further comprise means for allowing the solar panel housing to rotate around the mount.

### BRIEF DESCRIPTION OF THE DRAWINGS

It will be appreciated that the drawings are not necessarily to scale, with emphasis instead being placed on illustrating the various aspects and features of embodiments of the invention, in which:

FIG. 1 is a perspective view of a solar panel assembly attached to a watercraft trailer.

FIG. 2 is a perspective view of a solar panel assembly attached to a watercraft trailer.

FIG. 3 is a perspective view of a solar panel assembly and a reserve battery box attached to a watercraft trailer.

FIG. 4 is a top view of a solar panel housing holding two solar panels.

FIG. 5 is a close-up view of the base of a solar panel housing coupled to a housing mount.

FIG. 6 is an underside view of a solar panel housing.

FIG. 7 is a close up view of a base plate coupled to a trailer tongue.

FIG. 8 is a close up view of an underside of a base plate coupled to a trailer tongue.

FIG. 9 is top view of an opened reserve battery box.

FIG. 10 is an alternative base plate configured to accompany different sized trailer tongues.

FIG. 11 is another alternative base plate configured to accompany different sized trailer tongues.

FIG. 12 is an alternative solar panel housing configured to hold a single solar panel.

FIG. 13 is an exploded view of a preferred solar panel housing configured to be supported by a trailer stanchion.

FIG. 14 is an exploded view of a preferred solar panel housing supported by a horizontal mount.

FIG. 15 is an exploded view of a preferred solar panel housing supported by a boat bow mount.

### DETAILED DESCRIPTION OF THE ILLUSTRATED EMBODIMENTS

Embodiments of the present invention are described below. It is, however, expressly noted that the present invention is not limited to these embodiments, but rather the intention is that modifications that are apparent to the person skilled in the art and equivalents thereof are also included.

While the majority of the description below is directed to solar panel housings on boat trailers, additional preferred embodiments are directed to rotatable solar panel housings mounted on any suitable vehicle, trailer, machine, or structure, non-exclusively including, military vehicles, construction vehicle, road signs, boats, watercraft, car trailers, residential and commercial buildings, and the like.

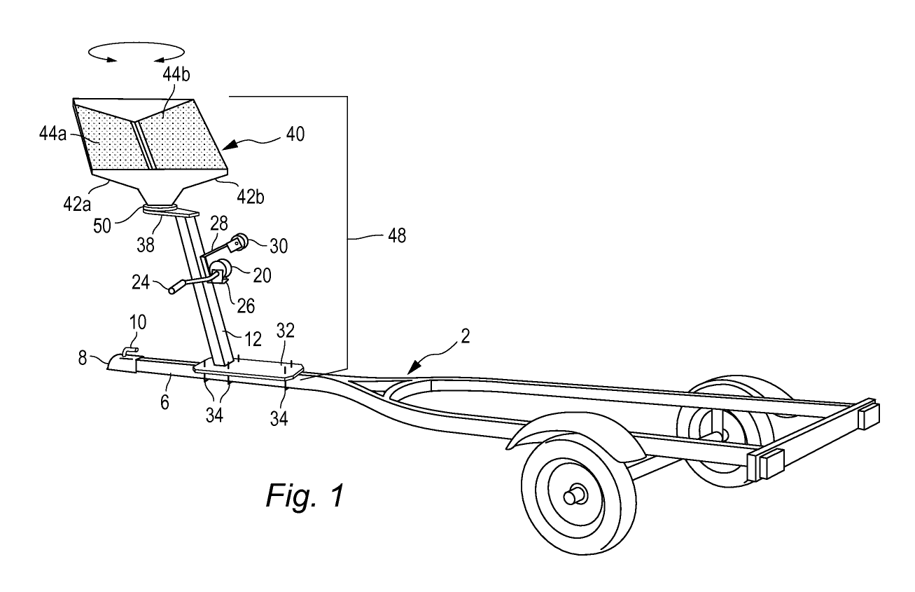

FIG. 1 shows a boat trailer 2 configured to receive and release a watercraft through its back end and releasably couple to a towing vehicle with its front end. More specifically the boat trailer 2 can include a tongue 6 having a hitch coupler 8 and hitching lock 10 for coupling to a tow hitch on a towing vehicle, such as a truck or SUV, for example. The hitch coupler 8 can be complementary to any towing hitch on the towing vehicle, such as a ball hitch for example. The specific boat trailer 2 shown is expressly non-limiting and any suitable watercraft trailer can be used with the teachings herein. Examples of watercraft trailers can non-exclusively include boats, canoes, kayak, sailboats, and the like. The use of the term “boat” herein relates to any suitable watercraft.

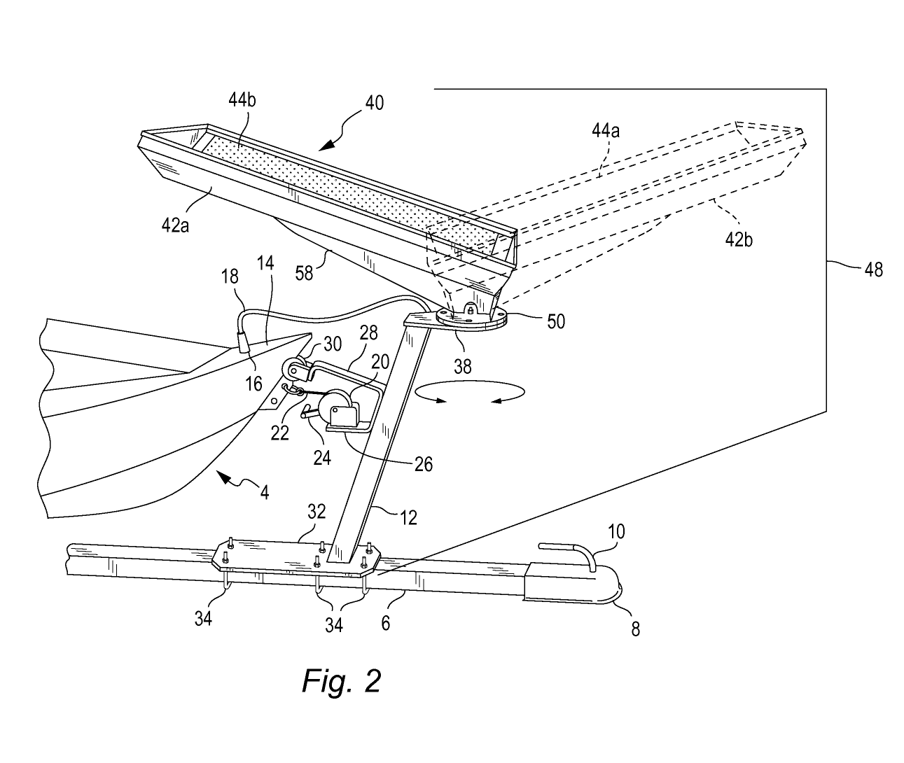

Advantageously, the boat trailer 2 includes a solar panel assembly 48 configured to charge a battery, that can be within a watercraft or a reserve battery. FIG. 2 shows a close-up view of a solar panel assembly 48. In general, preferred solar panel assemblies include a base plate 32, a stanchion 12, and a solar panel housing 40. The base plate 32 supports the assembly 48 and includes means for coupling to the trailer 2. More specifically, the base plate 32 can advantageously be configured to couple to the tongue 6 of the trailer 2. Alternatively, the base plate can be configured to couple to a horizontal crossbar positioned near the front of the trailer (not shown) depending on the specific construction of the trailer. Accordingly, embodiments herein directed to the trailer tongue are expressly contemplated to also be used with crossbar embodiments.

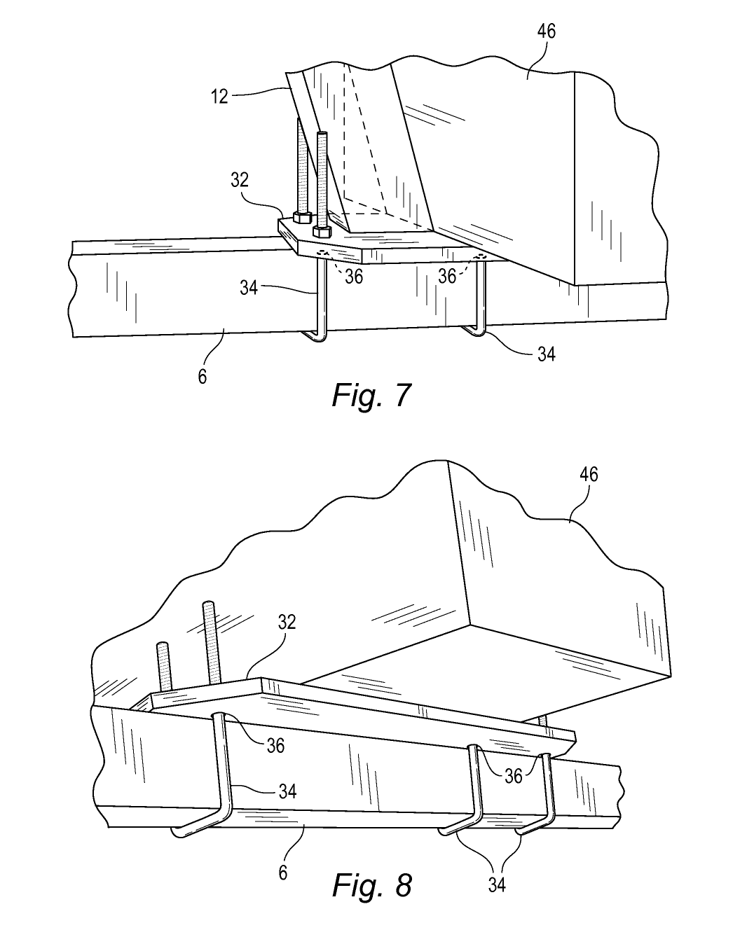

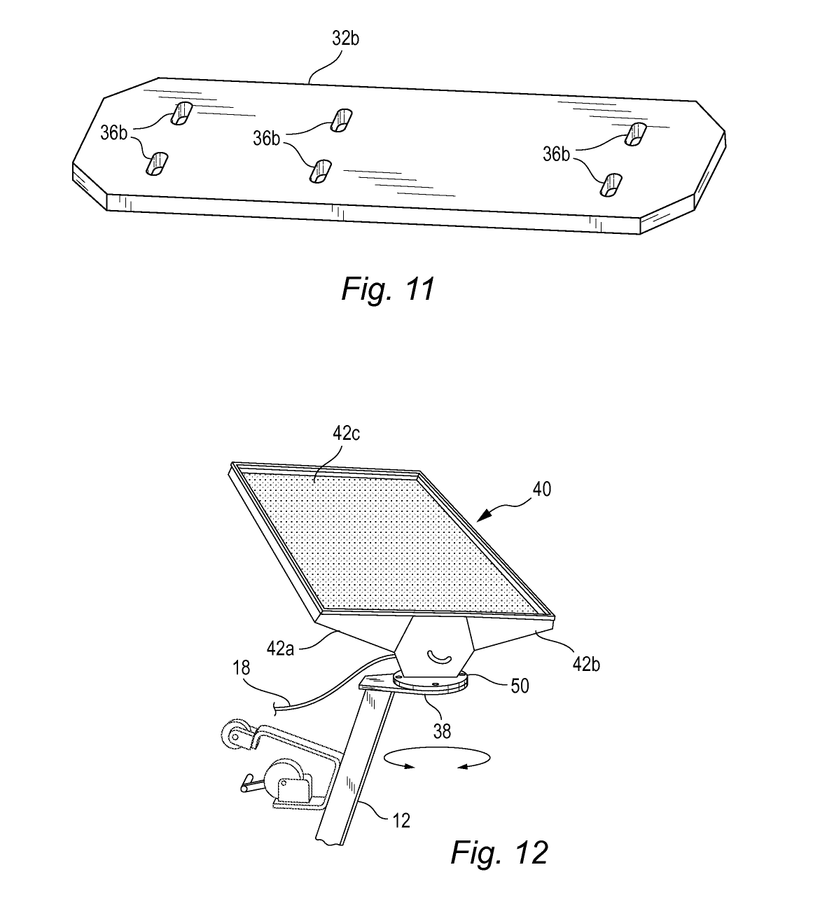

According to more specific embodiments, the base plate 32 can include means for releasable attachment to the tongue 6 of the trailer 2 such that it can be adjustably positioned along the length of the tongue 6 and secured at a desired position. Means for releasable attachment onto the tongue 6 of the trailer are advantageous in that the solar panel assemblies 48 provided herein can be coupled and removed from most boat trailers. As one example of means for releasable attachment, the base plate 32 can include a plurality of holes 36 configured to allow any suitable bolt, such as a U-bolt 34 to secure the base plate 32 to the tongue 6. FIGS. 7 and 8 provide close up views of U-bolts 34 securing the base plate 32 to the trailer tongue 6. As shown in FIGS. 7 and 8, the back side of the U-bolt 34 can be positioned against the underside the trailer tongue 6 such that the two prongs of the U-bolt 34 extend upwards through the holes 36 in the base plate 32. The U-bolts 34 can be tightened to the tongue 6 during attachment and loosened to release the base plate 32, such as when a user wants to either slide the solar panel assembly 48 along the length of the tongue 6 or to remove the assembly 48 completely. To accommodate different sized tongues 6 in different trailers, additional holes can be present in the base plate to allow for different sized U-bolts or other fastening means to secure the base plate to the tongue. As one example, FIG. 10, depicts a base plate 32a having outer holes 36 configured to receive a wider U-bolt for attachment to a wider tongue, and inner holes 36a to allow a narrower U-bolt to secure the base plate to a narrower tongue 6. As one example, the outer holes 36 can be used to secure the base plate 32a to a 4 inch wide tongue, while the inner holes 36a can allow attachment to a 2 inch wide tongue. Three, four, or more hole sets are also readily contemplated herein. As an alternative to utilizing multiple hole sets for incremental adjustment, the base plate 32b shown in FIG. 11 can include one or more sets of lateral slots 36b configured to receive suitable locking bolts and that allow for continuous adjustment to attach to different widths of tongues. Any suitable means for attaching the base plate 32 to the tongue 6 can be used with the teachings herein, non-exclusively including non-releasable attachment means such as welding, and releasable attachment means such as bolts, clamps, and screws, and the like, for example.

According to preferred embodiments, the base plate 32 is positioned at the front of the trailer 2 such that it is in front of the boat 4 when the boat 4 is secured to the trailer 2. According to further beneficial embodiments, the underside of the base plate 32 is planar, or substantially so, such that it can rest level on top of the tongue 6. The base plate 32 can run along the length of the tongue 6 of the trailer to any suitable distance as desired to provide sufficient support for the stanchion 12 and the solar panel housing 40. Preferably, the base plate 32 is made of a suitable material such as metal, and more preferably, aluminum or steel.

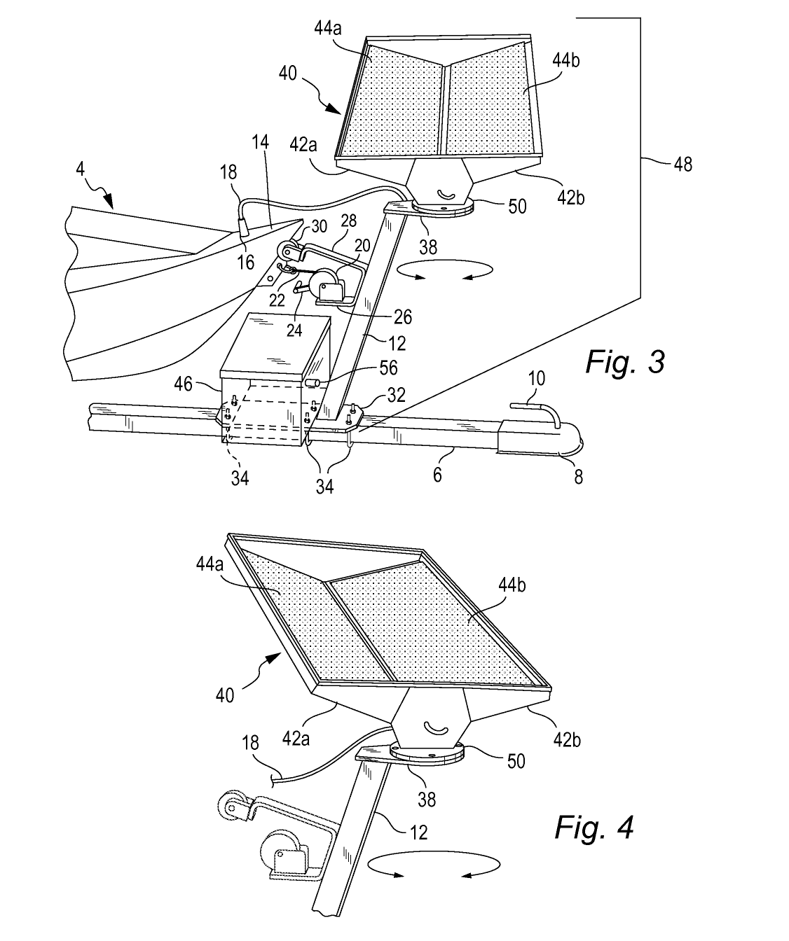

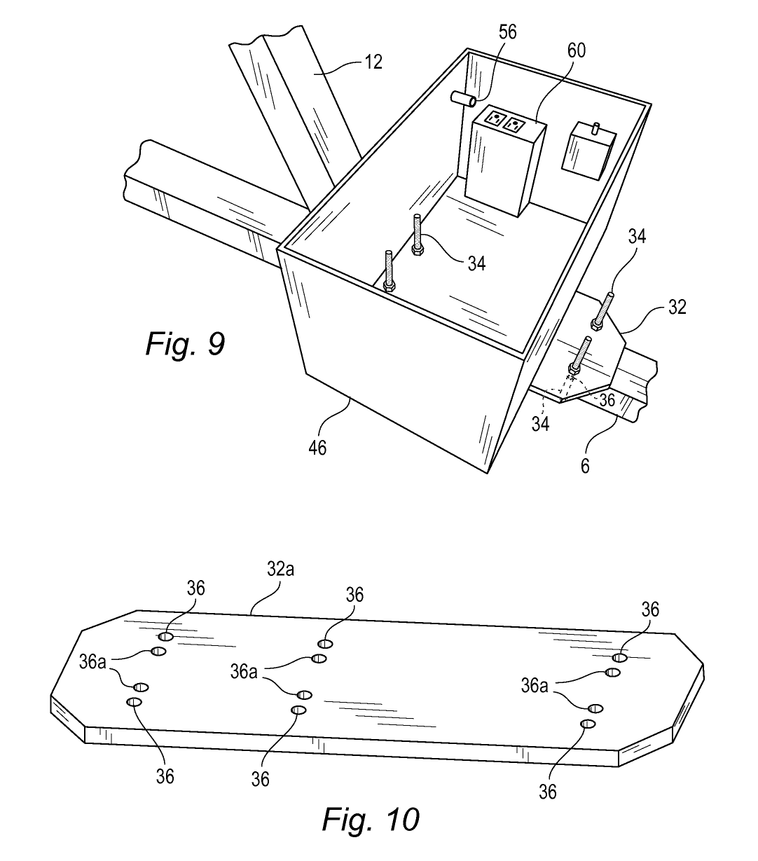

While FIGS. 1 and 2 show the trailers herein without a reserve battery housing, FIGS. 3, 6, and 7-9 show an optional reserve battery housing 46 coupled to the base plate 32. As shown in FIG. 9, any suitable bolt, such as a U-bolt 34 can be positioned under the tongue 6 such that its prongs are inserted through holes on the base plate 36 and through apertures on the bottom of the battery housing 46. Other suitable methods of fastening the battery housing 46 to the trailer 2 can be releasable, such as through the use of pins, bolts, clamps, and the like, or non-releasable such as through welding. These particular embodiments are expressly non-limiting as the reserve battery housing 46 can be positioned at other locations on the trailer 2, or even on the stanchion, and include any suitably shaped housing for holding a reserve battery 60. Preferably the reserve battery housing 46 includes sufficient space to charge one or more batteries, including the batteries used to power a boat 4 or car, or other batteries as well. More specifically the housing 46 can be configured to house a battery such as 12 or 24 volt battery that can optionally be used to power a boat 4. The use of a reserve battery 60 is advantageous in that it allows a user to charge the reserve battery 60 while the boat 4 is utilizing the power of the main battery. When the power is exhausted from the main battery, a user can simply install the reserve battery 60 into the boat 4 and place the main battery into the battery housing 46 to allow charging with the one or more solar panels 44a and 44b.

The battery housing 46 is preferably water proof or at least water resistant to protect the housed battery 60 and includes an opening, such as a lid for inserting and removing the battery 60. The battery housing 46 preferably includes a socket 56 for operably coupling the electrical cord 18 to the reserve battery 60. FIG. 9 shows an exemplary battery housing 46 opened to provide an internal view. The reserve battery 60 is preferably removably mounted within the housing 46 to prevent unnecessary movement, especially when the trailer 2 is being towed.

The lower portion of the stanchion 12 can be coupled to the base plate 32 using any suitable means such as welding, bolts, screws, clamps, and the like. Preferably the stanchion 12 extends upward from the base plate 32 and even more preferably at a forward angle, away from the secured boat and towards the towing vehicle. The height of the stanchion 12 can vary depending on the height and the length of the boat 4 being towed. Advantageously, the trailers and stanchions provided herein can work with boats between 8-28 feet in length, as an example. Furthermore, preferred ranges of stanchion height can be between 2-5 feet in height, for example. According to alternative embodiments, the stanchion can be telescoping to allow for variable height adjustment.

The body of the stanchion 12 can advantageously include any suitable winch 20 for pulling a boat 4 forwards on the trailer 2. As shown in FIG. 2, the winch 20 can include a cord 22 (e.g., wire, nylon fabric, rope) that can coil around a spool and uncoil outward and include means for coupling to the boat 4. Any suitable releasable coupling means can be used to attach the cord 22 to the bow of the boat 4 such as a carabineer or clip through a bow eye or bow hook. When the winch 20 is reeled in, the coupled boat 4 is pulled forward on the trailer 2. Likewise when the winch 20 is unreeled, the cord 22 is let out allowing for more slack such that the boat 4 can be slid off the back of the trailer 2, into the water. As one optional embodiment, the winch 20 can be mounted on top of a sufficiently strong winch bracket 26 that extends towards the back of the trailer 2. The winch 20 can be manually operated by a hand crank 24 or configured to utilize power. According to alternative embodiments, when a power winch is utilized, it can be operably coupled to the one or more solar panels 44a and 44b such as to receive its power source.

The stanchion 12 can also include a bow stop 30 that is preferably coupled to a horizontal extension 28 that is cantilevered towards the back of the trailer 2 and positioned above the winch 20. The bow stop 30 can be any suitable device for receiving the bow of the boat 4 when the winch 20 has pulled the boat 4 to its foremost position on the trailer 2. Non-exclusive examples of bow stops can non-exclusively include rollers, and padded V-shaped receiving members.

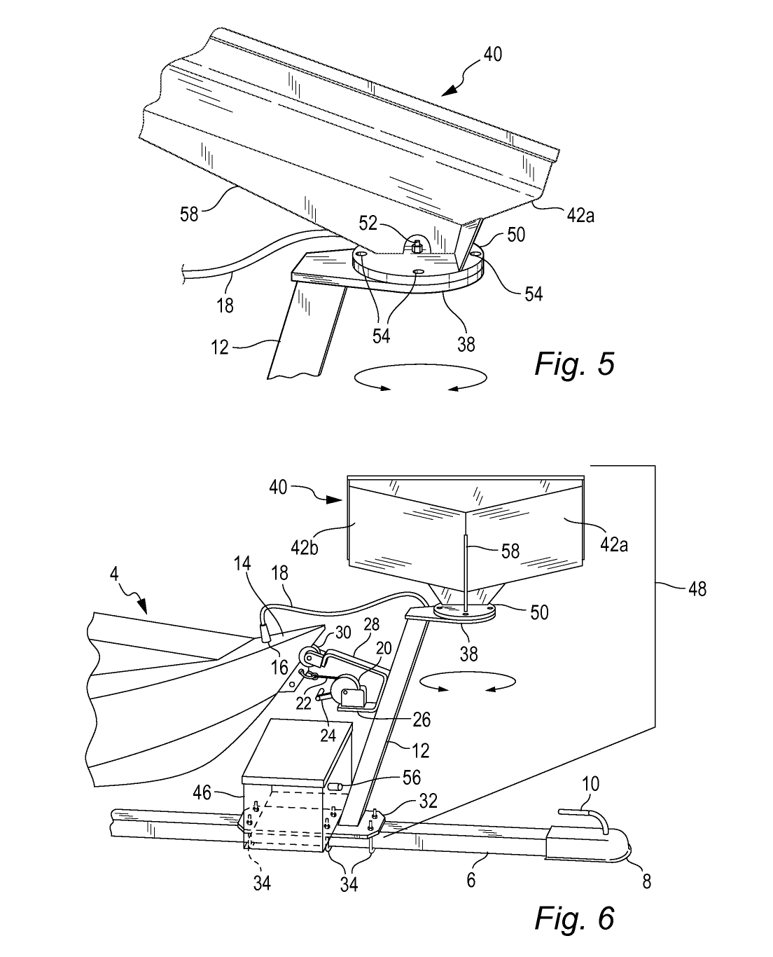

The top portion of the stanchion 12 includes a housing mount 38 that supports the solar panel housing 40 above. The housing mount 38 preferably extends towards the front of the trailer 2 from the top of the stanchion 12 such that it is parallel with the tongue 6 of the trailer 2, or substantially so, although any suitable load bearing mount can be used to support the solar panel housing 40 above. Preferably, the housing mount 38 includes means for allowing the base 50 of the solar panel housing 40 to rotate around, preferably a full 360 degrees. As one example, FIG. 3 depicts the solar panel housing 40 rotated 90 degrees. The means for rotation can expressly be manual or automated. As one example, FIG. 5 depicts the circular base 50 of a solar panel housing 40 configured to be rotatable around a central screw 52 coupling the base 50 to the housing mount 38.

According to more specific embodiments, apertures 54 can be positioned through the base 50 at desired locations to allow a bolt, clamp, pin, or other stop device to secure the base 50, and thus the solar panel housing 40 at a desired position. FIG. 5 shows four apertures 54 at 90 degree intervals, although more or less apertures can be used as desired. For example, apertures can be positioned at every 45, 30, or 15 degrees of the housing base 50, for example. For embodiments directed to automated rotation of the base 50 of the solar panel housing 40, a motor can readily be used to automate the rotation of the housing 40 in accordance with the predicted sunlight path at the trailer 2 location. According to even more specific embodiments, the powered or automated means for rotation can be operably coupled to the one or more solar panels 44a and 44b such as to provide a power source. When the trailer 2 is being towed by a towing vehicle on roads, it is preferred for aerodynamic reasons to position the housing 40 in a travel position where it is cantilevered from its base 50 towards the boat 4, such that is parallel with the trailer tongue 6. The travel position of the solar panel housing 40 is shown in solid lines in FIG. 2. Alternatively, the housing mount can be configured to be rotatable along the top of the stanchion while the base of the housing base is configured to be stationary.

As shown in FIGS. 4 and 6, the solar panel housing 40 is supported by its base 50 positioned on top of the housing mount 38. Additionally, the body of the solar panel housing 40 can advantageously include downwardly slanting left and right sides 42a and 42b that help protect the one or more housed solar panels 44a and 44b from road debris when the trailer 2 is being towed. The downwardly slanting right and left sides 42a and 42b can also act to increase the aerodynamic properties of the housing 40. According to certain embodiments, the downwardly slanting sides can terminate at a bottom section such as rectangular-shaped, or otherwise planar bottom, such that the housing is in the general shape of a trough, for example (not shown). According to this embodiment, the front and back sides of the housing can be in the general shape of trapezoid, or substantially so. Alternatively, a preferred solar panel housing 40 includes two downwardly converging sides 42a and 42b that form a V-shaped cross-section. According to this embodiment, the front and back sides of the housing 40 can be in the general shape of a triangle, or substantially so. Advantageously a bottom fin 58 can traverse alongside the underside of the housing 40, such as along the border where the two sides 42a and 42b converge. The bottom fin 58 can include a wider portion secured to the housing base 50 such that it tapers upward along the converging border of the two sides 42a and 42b, such as in the shape of a triangle, for example. Preferably, the housing 40 is constructed of a rigid structural material, such as metal, and more preferably aluminum and/or steel. According to non-preferred embodiments, any suitably shaped solar panel housing can be used with the teachings herein.

FIG. 4 shows a preferred embodiment wherein right and left solar panels 44a and 44b are positioned within the solar panel housing 40. More specifically, the solar panels 44a and 44b are respectively installed on the inner faces of the right and left converging sides 42a and 42b of the housing 40. This particular configuration is advantageous in that the solar panels 44a and 44b are more protected from road debris by the slanted sides 42a and 42b. The arrangement and number of solar panels shown in FIG. 4, is expressly non-limiting, as preferred housings described herein can include a single panel or more than 1 panel. As another example, FIG. 12 depicts the housing 40 having a single solar panel 42c that is installed level or substantially level across the two slanted sides 42a and 42b. It is preferred under this particular embodiment, to have the solar panel 42c slightly recessed within the housing 40 to still allow the slanted sides 42a and 42b to offer protection from road debris. Accordingly to other embodiments, 3, 4, 5, 6, or more solar panels can be used with the housing described herein having any suitable shape or patterned configuration.

Any suitable solar panels can be used with the teachings herein. Preferably the solar panels as a collection can provide power to a boat 4 having a battery. Boat batteries that fully power the motor of the boat and batteries for sail and gas operated boats are also readily contemplated herein. In particular, the one or more solar panels 44a and 44b are preferably configured to fully charge a 12 or 24 volt battery. Optionally, the solar panels can also power a power winch 20, and means for rotating the solar power housing 40. According to further embodiments, the one or more solar panels 44a and 44b can also power portable electronic devices, such as devices useful in camping and during an emergency, including low voltage lighting, pumps, laptops, microwaves, water filtration systems, radios, cell phones, televisions, generators and the like, for example.

Means for coupling the one or more solar panels 44a and 44b to the boat 4 are preferably present in the solar panel housing 40. FIG. 3 depicts an electrical cord 18 having a first end operably coupled to the solar panels 44a and 44b and a second end have means for operably coupling to a socket in communication with a battery. As one example, shown in FIG. 3, the forward deck 14 of the boat 4 can include a socket 16 for receiving the second end of the electrical cord 18. Preferably the second end of the electrical cord 18 and/or the socket 16 are adapted to be waterproof or at least water resistant with the use of gaskets, caps, or rubber housings, for example. The socket 16 in the boat is preferably in operable communication with the boat's battery and can be positioned in any suitable spot on the boat, such as on either the port or starboard side, or bow of the boat as well. These mentioned positions are disadvantageous as in they expose the socket unnecessarily to water. As the solar panel housing 40 is positioned on the front of the trailer 2, it is preferred that the boat's socket is on the forward deck, not on the bow or sides, and is not present near the aft of the boat, otherwise an unnecessarily long electrical cord would be utilized. For non-preferred embodiments, where a battery or socket is located near the aft of a boat, a long electrical cord can be used or extension cords and/or alligator clips can be used to elongate the electrical cord 18. For embodiments, wherein the solar panels power the winch and/or rotating means, these devices can also include sockets for receiving the second end of the electrical cord 18, or alternatively, more than one electrical cord in operable communication with the solar panels can be used.

Advantageously, the electrical cord 18 is sufficiently long enough to be plugged into the socket 16 of the boat 4 while allowing the solar panel housing 40 to be rotatable 360 degrees around the top of the stanchion 12. Additionally, it is preferred that the electrical cord 18 is sufficiently long to reach the socket 56 within the reserve battery housing 46 and still allow 360 rotation of the solar panel housing 40 around the top of the stanchion 12.

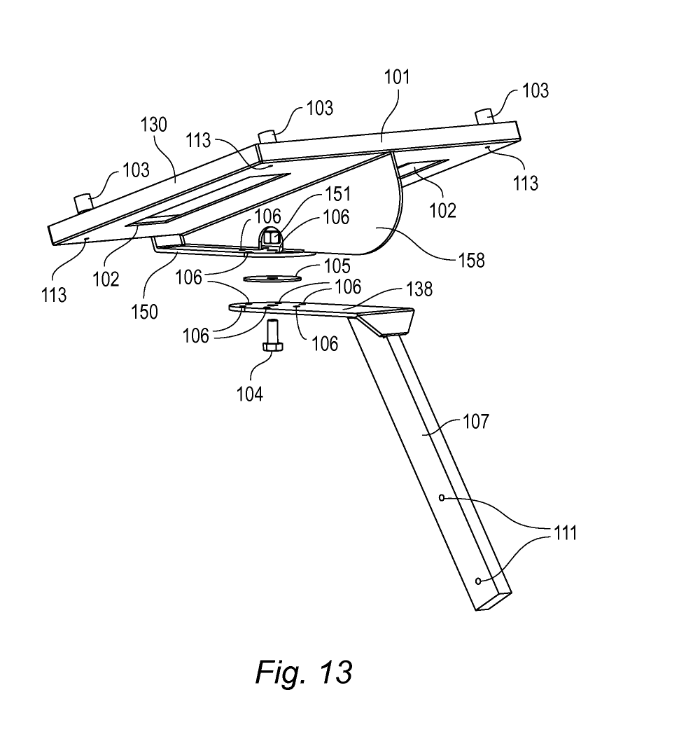

FIG. 13 depicts an alternative preferred embodiment solar panel housing 101. Embodiments and features not expressly described below with reference to FIGS. 13-15 can be incorporated from the description above, where suitable. While shown configured to support two solar panels, different sized housings can also be used to support 1 or more solar panels. The perimeter of the housing 101 preferably includes raised flanges 130, or protective barriers to protect the mounted solar panels within the housing from debris or other hazards that could potentially damage the panels. The perimeter of the housing 101 is preferably similar to the perimeter of the mounted solar panel(s) to provide a close fit. While shown as perpendicular to the back panel of the housing 101, the flanges can be angled inward or outward as well. The flanges 130 can wrap around the entire perimeter, or substantially so. The flanges 130 also can act as a barrier to prevent the solar panels from falling off the housing 101, especially during traveling.

The solar panel housing 101 is preferably constructed of a rigid material capable of supporting the solar panels, and is thus preferably made of metal, such as aluminum or steel, for example. The back panel is preferably angled with respect the housing base 150 to allow for optimal sun exposure. This can be done utilizing a bottom fin 158 traversing along the underside of the housing 101, such as in the middle of the back panel, or substantially so, and coupling to the top of the housing base 150. It is also preferred that the angle of the solar panel housing 101 is adjustable depending upon the geographic location of the housing 101, time of day, and season, and the like. This adjustment can be manual or automatic (e.g., motorized) and set to an electric timer, or computer for example.

The housing 101 can also include vibration dampeners 103, preferably having some resiliency to act as shock absorbers. Preferred resilient materials for the dampeners 103 can be a compressible elastomer such as soft rubber, or silicon rubber, but can also be springs made of metal or plastic, for example. The solar panel can be positioned on top of these dampeners 103. The dampeners 103 are especially useful when the solar housing 101 is used on a vehicle or a trailer to help absorb shocks incurred during traveling. The dampeners 103 are also advantageous even for non-traveling embodiments, such as when the housing 101 is exposed to adverse weather or environmental conditions, such as high wind or on turbulent water, for example. The shock absorption from the dampeners 103 can prevent damage to the mounted solar panels during traveling and from inclement environments. While only four cylindrical dampeners 103 are shown at the corners of the back panel of the housing 101, additional or fewer, and alternatively shaped dampeners, can be placed in other or additional locations on the back panel to support the solar panels in the housing 101. Dampeners can be positioned in the housing 101 to support each corner of each installed solar panel, for example. According to preferred embodiments, the dampeners 103 include apertures 113 that allow for the solar panels to be secured to them. The solar panels, dampeners 103 and housing 101 can be coupled using any suitable means. More specifically, the dampeners 103 can include an aperture 113, threaded or otherwise, to allow a bolt to traverse through a solar panel, the dampener 103, and the underside of the housing 101 to be secured by a nut, for example. This embodiment allows the dampeners 103 to be secured to both the solar panel and the housing 101. Alternatively, a bolt can be passed through a solar panel and then be threaded and locked into the dampener 103 itself, without traversing through the underside of the housing 101. According to this embodiment, the dampener 103 can be secured to the housing 101 independently, such as by adhesive, bolts, and the like.

An additional preferred feature of the housing 101 is the use of passive heat dissipating slots 102. While only two rectangular slots 102 are shown on the back panel of the housing 101, additional or fewer slots, and different shaped slots, can be placed in other or additional locations on the back panel of the housing 101. Solar panels generate heat during use, and the slots 102 allow for this generated heat to disperse in order to prevent damage to the working solar panels. This can extend the life and efficiency of the working solar panels. Preferred slots 102 are positioned directly behind where the solar panels are placed in the housing 101 but have a surface area of less than that of the above-positioned solar panel and are sized to prevent the solar panel from falling through, or otherwise being unsupported by the back panel of the housing 101. Preferred areas of the heat dissipation slots 102 can be more than a ⅓ the surface area of the back panel of the housing 101 but preferably no more than ½ the surface area of the back panel of the housing 101. Additionally, the heat dissipation slots can be louvered.

With continued reference to FIG. 13, the housing 101 is supported by a housing base 150 that is configured to couple to a housing mount 138 having means for allowing rotational movement, to allow for the housing 101 to rotate around the housing mount 138 at different angles in a 360 degree range of motion. These rotational means can be automated or manual. As one preferred example, the means for rotation include apertures 106 in the housing base 150 and the housing mount 138 that align with each other. The housing 101 can be rotated around the housing mount 138 to the desired angle, aligning the respective apertures 106, and then a pin or other securing means can be placed through the aligned apertures 106 to set the desired rotational degree. While six apertures 6 are shown in the housing base 150 and mount 138, (representing approximately 60 degrees of rotation between neighboring apertures 106) more or less apertures can be utilized to allow for more or less rotational adjustment respectively.

The housing 101 can be coupled to the housing mount 138 using any suitable means such as a bolt 104 and a coupling nut 151. Additionally a washer or a friction disc 105 can optionally be placed between the housing mount 138 and the housing base 50. The disc can allow for smooth rotation of the housing 101 and can also act as a vibration dampener of the housing 101. Preferred materials for the disc 105 can include a hard, smooth, thermoplastic, for example.

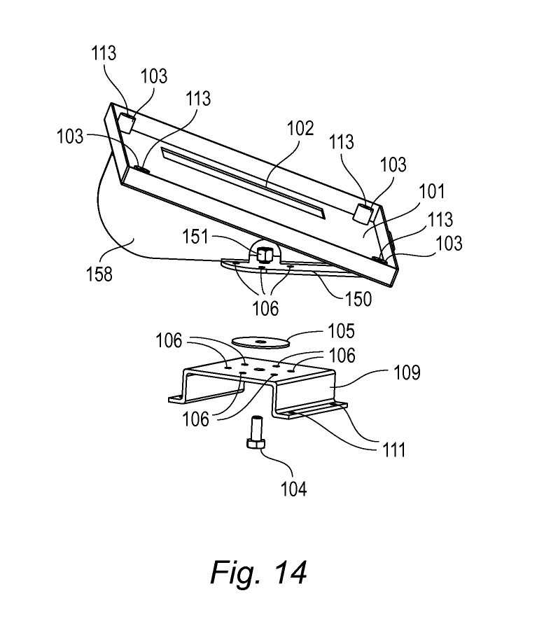

FIG. 13 shows a preferred housing 101 having a support leg 107 that can be configured to mount into a trailer stanchion. Alternatively, the support leg can act as a sleeve to be positioned over the stanchion. The support leg 107 can include holes 111 to allow for height adjustment and attachment to a trailer stanchion, such as through locking pins. The housing 101 and alternative embodiments discussed above can also readily be mounted on vehicles, equipment, machines, or any suitable buildings. For example FIG. 14 shows a preferred solar panel housing 101 configured to mount to a horizontal mount 109. As with the housing base 50 described above, the horizontal mount 109 can utilize means for allowing rotational movement of the housing 101. Mounting holes 111 allow for the horizontal mount 109 and supported housing 101 to be mounted on any desired vehicle, building, machine, or other suitable structure desired to be solar powered. While the horizontal mount 109 is shown as elevated, planar horizontal mounts 109 are also readily contemplated herein.

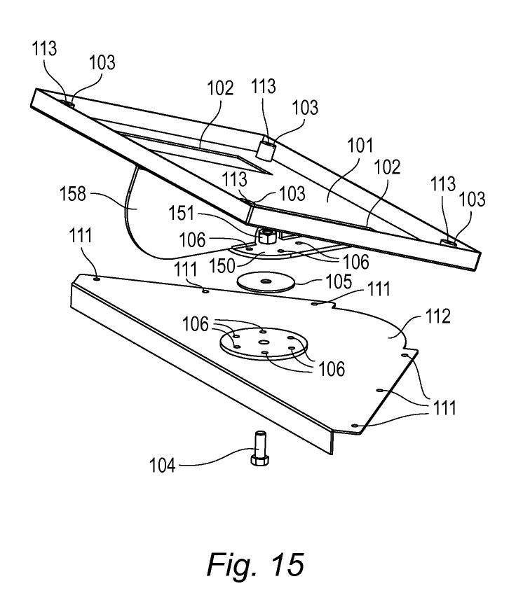

FIG. 15 shows a preferred bow mount 112 being utilized to secure the solar panel housing 101 to the bow of a boat and to allow for rotational movement of the housing 101 around the mount 112. The bow mount 112 can be shaped to conform to the shape of the top of the bow of the boat for easier, secure attachment. Similar to the housing mount 138 and the horizontal mount 109, the bow mount 112 has means for rotation to allow for the supported housing above 101 to rotate around to more efficiently capture sunlight. Mounting holes 111 allow for the bow mount 112 to be secured to the top, bow of a boat. The bow mount 112 or the horizontal mount 109, or similar mounts, can be used to secure the solar panel housing 101 to any suitable vehicle, such as a car, watercraft, truck, construction vehicle, military vehicle, flying vehicle, golf cart, structures, equipment, or any suitable residential or commercial building.

It is also important to note that the solar panel housing 40 shown in FIG. 2 and described above can also be mounted on boats, vehicles, other trailers, or structures as well as utilizing a support leg 107, horizontal mounts 109 or bow mounts 112.

The invention may be embodied in other specific forms besides and beyond those described herein. The foregoing embodiments are therefore to be considered in all respects illustrative rather than limiting, and the scope of the invention is defined and limited only by the appended claims and their equivalents, rather than by the foregoing description.

1. A solar panel housing assembly comprising:
a solar panel housing having a back panel with one or more heat dissipating slots, configured such that one or more solar panels can be supported by the back panel, and a solar panel housing base, wherein the back panel is angled with respect to the solar panel housing base; and
a mount comprising means for securely coupling to the top of a support structure and having a topside having means for coupling to the base of the solar panel housing, wherein the mount and the solar panel housing base further comprise means for allowing the solar panel housing to rotate around the mount.

2. The solar panel housing assembly of claim 1, wherein the means for securely coupling to the base of the solar panel housing and the means for allowing the solar panel housing to rotate, comprise a pivot bolt.

3. The solar panel housing assembly of claim 2, wherein the base of the solar panel housing and the mount each comprise a plurality of holes positioned at intervals of defined rotational degrees that can be aligned with other such as to allow a user to lock the solar panel housing at a particular degree of rotation.

4. The solar panel housing assembly of claim 3, further comprising a substantially smooth disc positioned between the mount and the base of the solar panel housing, that ameliorates friction between the mount and the base of the solar panel housing and can absorb shock.

5. The solar panel housing assembly of claim 1, further comprising a support fin extending upwards at an angle from the base of the solar panel housing coupled to the underside of the back panel of the solar panel housing.

6. The solar panel housing assembly of claim 1, wherein the mount is substantially the same shape as the top of a boat bow.

7. The solar panel housing assembly of claim 1, wherein the underside of the mount is coupled to a support leg that is a sized to fit into a trailer stanchion and configured to attach to said stanchion.

8. The solar panel housing assembly of claim 1, wherein a flange rises from the perimeter around the back panel.

9. The solar panel housing assembly of claim 1, further comprising compressible dampeners positioned on the topside of the back panel of the solar panel housing.

10. The solar panel housing assembly of claim 9, wherein the dampeners include apertures for bolts to traverse through.

11. The solar panel housing assembly of claim 10, wherein the apertures in the dampeners align with apertures positioned on the back panel of the solar panel housing.

12. The solar panel housing assembly of claim 11, wherein the apertures in the dampeners and the apertures in the back panel of the solar panel housing are threaded.

13. The solar panel housing of claim 9, wherein the dampeners are made of rubber.

14. The solar panel housing of claim 1, wherein the one or more heat dissipating slots are at least ¼ the surface area of the backside of a solar panel, when the solar panel is positioned on top of the one or more heat dissipating slots.

15. A solar panel housing assembly comprising:
a solar panel housing having a back panel configured such that one or more solar panels can be supported by the back panel, the back panel further comprising compressible dampeners positioned on the topside of the back panel of the solar panel housing, and a solar panel housing base, wherein the back panel is angled with respect to the solar panel housing base; and
a mount comprising means for securely coupling to the top of a support structure and having a topside having means for coupling to the base of the solar panel housing, wherein the mount and the solar panel housing base further comprise means for allowing the solar panel housing to rotate around the mount.

16. The solar panel housing assembly of claim 15, wherein the dampeners include apertures for bolts to traverse through.

17. The solar panel housing assembly of claim 16, wherein the apertures in the dampeners align with apertures positioned on the back panel of the solar panel housing.

18. The solar panel housing assembly of claim 17, wherein the apertures in the dampeners and the apertures in the back panel of the solar panel housing are threaded.

19. The solar panel housing assembly of claim 15, wherein the means for securely coupling to the base of the solar panel housing and the means for allowing the solar panel housing to rotate, comprise a pivot bolt and wherein the base of the solar panel housing and the mount each comprise a plurality of holes positioned at intervals of defined rotational degrees that can be aligned with other such as to allow a user to lock the solar panel housing at a particular degree of rotation, and further comprising a substantially smooth disc positioned between the mount and the base of the solar panel housing, that ameliorates friction between the mount and the base of the solar panel housing and can absorb shock.

20. The solar panel housing assembly of claim 19, further comprising a support fin extending upwards at an angle from the base of the solar panel housing coupled to the underside of the back panel of the solar panel housing.
